(19) United States
(12) Patent Application Publication
(10) Pub. No.: US 2020/0343695 A1
(43) Pub. Date: Oct. 29, 2020

(54) WAVELENGTH DIVISION MULTIPLEXING OPTICAL MODULE

(71) Applicant: Hewlett Packard Enterprise Development LP, Houston, TX (US)

(72) Inventors: Sagi Varghese Mathai, Sunnyvale, CA (US); Paul Kessler Rosenberg, Sunnyvale, CA (US); Wayne Victor Sorin, Mountain View, CA (US); Michael Renne Ty Tan, Menlo Park, CA (US)

(21) Appl. No.: 16/397,083

(22) Filed: Apr. 29, 2019

(51) Int. Cl. H01S 5/40; H01S 5/022; H01S 5/42; H01S 5/042; H01L 31/02; H01L 25/04; H01L 23/13; H01L 23/538; H01L 23/00; H04B 10/25; H04J 14/02

(52) U.S. Cl. CPC H01S 5/4012; H01L 31/02327; H01S 5/423; H01S 5/02284; H01S 5/0425; H01L 31/02002; H01L 25/042; H01L 23/13; H01L 23/5385; H01L 23/5386; H01L 24/16; H04B 10/25; H04J 14/02; H01L 2224/16227; H01L 2924/12042; H01S 5/02288; H01S 5/02272; H01S 5/0224

(57) ABSTRACT

Examples herein relate to optical modules. In particular, implementations herein relate to optical modules that include top-emitting VCSELs and/or top-entry photodetectors. The optical modules include a substrate having opposing first and second sides. The optical modules further includes a first interposer having opposing first and second sides and a plurality of top-emitting vertical-cavity surface-emitting lasers (VCSELs). The VCSELs are flip-chipped to the second side of the first interposer such that they are disposed between the substrate and the first interposer. The VCSELs are configured to emit optical signals having different wavelengths. The optical signals are configured to be combined and transmitted over a single optical fiber. The optical modules include a plurality of electrical conductors forming electrical paths between electrical contacts of the top-emitting VCSELs and the substrate.

### BACKGROUND

Optoelectronic communication (e.g., using optical signals to transmit electronic data) is becoming more prevalent as a potential solution, at least in part, to the ever increasing demand for high bandwidth, high quality, and low power consumption data transfer in applications such as high performance computing systems, large capacity data storage servers, and network devices. Wavelength division multiplexing (WDM) is useful for increasing communication bandwidth by combining and sending multiple data channels or wavelengths from multiple optical sources over an optical fiber.

### BRIEF DESCRIPTION OF THE DRAWINGS

Certain examples are described in the following detailed description and in reference to the drawings, in which:

FIG. 1A schematically illustrates a section view of a block diagram of an example of an optical module according to the present disclosure;

FIG. 1B schematically illustrates a section view of a block diagram of another example of an optical module according to the present disclosure;

FIG. 1C schematically illustrates a section view of a block diagram of another example of an optical module according to the present disclosure;

FIG. 2A schematically illustrates a section view of a block diagram of another example of an optical module according to the present disclosure;

FIG. 2B schematically illustrates a section view of a block diagram of another example of an optical module according to the present disclosure;

FIG. 2C schematically illustrates a section view of a block diagram of another example of an optical module according to the present disclosure;

FIG. 3A schematically illustrates a top section view of a block diagram of an example die layout of an array of optical modules according to the present disclosure; and

FIG. 3B schematically illustrates a top section view of a block diagram of another example die layout of an array of optical modules according to the present disclosure.

### DETAILED DESCRIPTION OF SPECIFIC EXAMPLES

The present disclosure describes various examples of a WDM optical module that includes a plurality of laser sources to emit and/or a plurality of photodetectors to receive optical signals having different wavelengths. For example, the laser sources can be top-emitting vertical-cavity surface-emitting lasers (VCSELs) and the photodetectors can be top-entry photodetectors flip-chipped to an interposer. A multiplexer can be used to join the optical signals emitted by the VCSELs through the interposer together before transmitting them over an optical fiber, and a demultiplexer can subsequently be used to separate the optical signals transmitted by the optical fiber to be received by each photodetector, as described in more detail below.

The interposer can be constructed of glass or other suitable materials with a relatively high-index of refraction (e.g., GaAs, GaP, GaN, InP). The interposer is disposed over or above a substrate such that the top-emitting VCSELs or the top-entry photodetectors are disposed between the interposer and the substrate. As described herein, the “substrate” can refer to an organic build-up substrate, another interposer (e.g., a Si-interposer), integrated circuit (e.g., ASIC), chip, die, or printed circuit board depending on the application. Further, the optical module includes electrical conductors forming electrical paths between top-side electrical contacts of the top-emitting VCSELs (or the top-entry photodetectors) flip-chipped to the interposer and the substrate thereunder. The substrate can further include electrically conductive traces or vias to pass electrical signals to or from the electrical conductors to an integrated circuit (e.g., an ASIC, driver integrated circuit, receiver integrated circuit) for driving the top-emitting VCSELs or processing electrical signals converted by the top-entry photodetectors.

An “optical fiber” as described herein can refer to a single optical fiber (e.g., including a core and a cladding) to provide unidirectional or bidirectional optical communication, can refer to a bidirectional pair of optical fibers (e.g., each including a core and a cladding) to provide both transmit and receive communications in an optical network, or can refer to a multi-core fiber, such that a single cladding could encapsulate a plurality of single-mode cores.

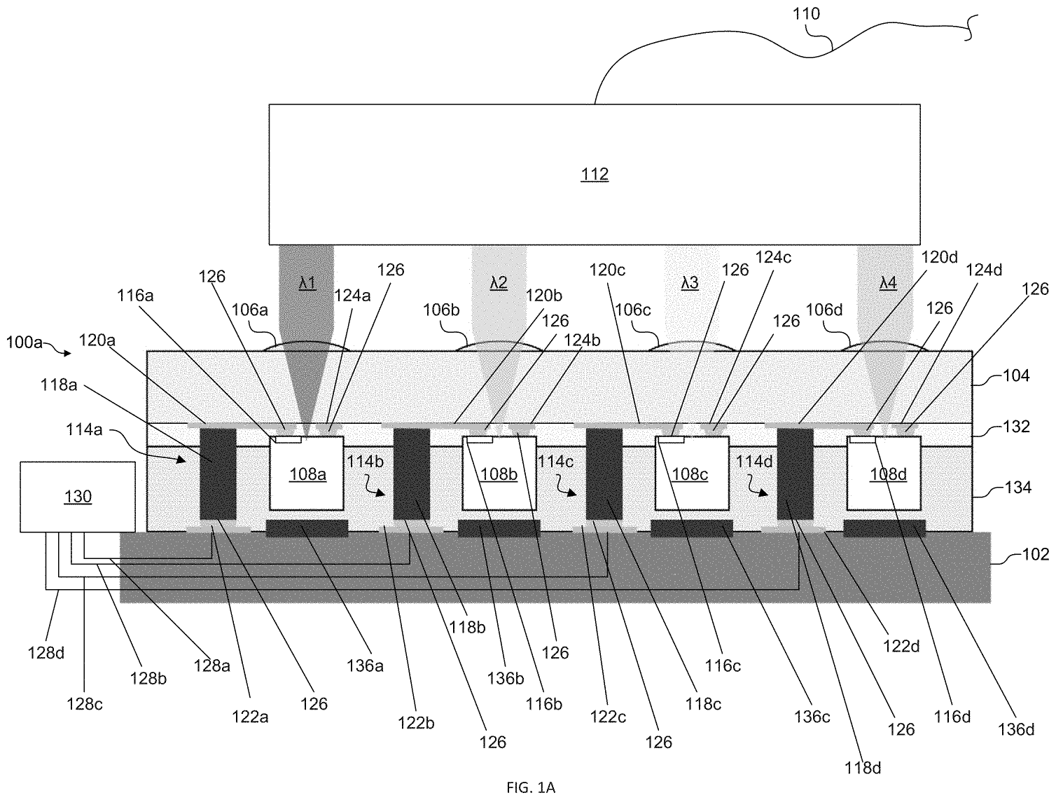

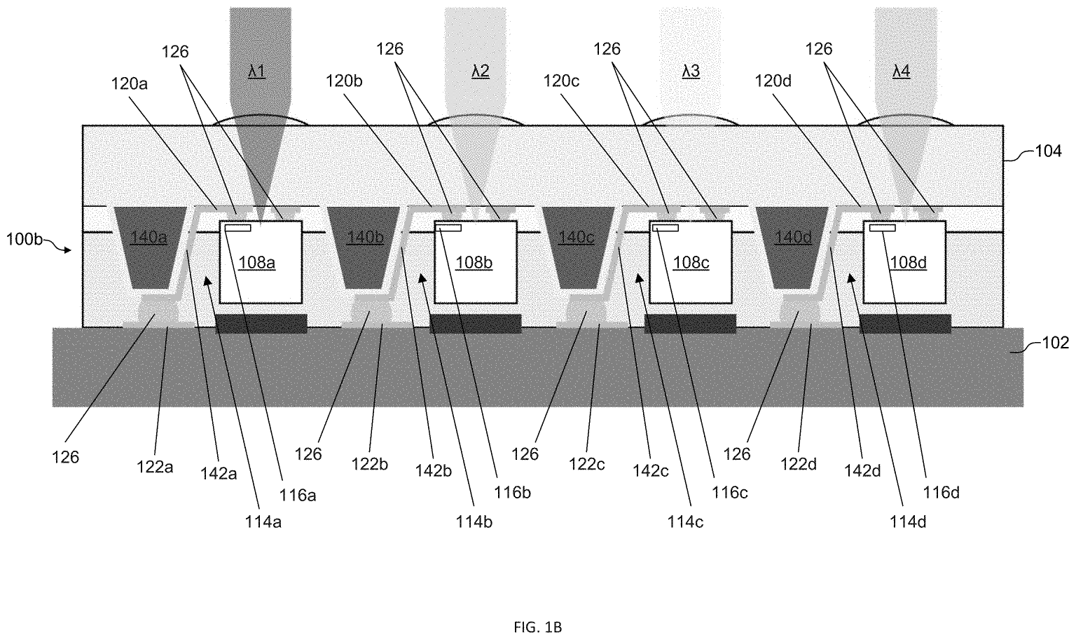

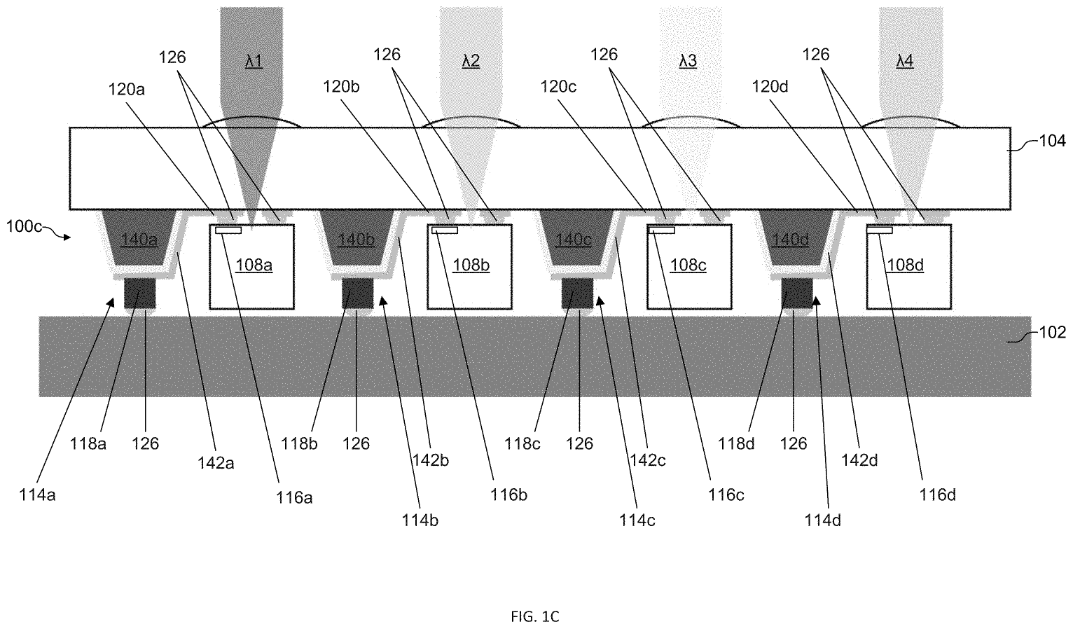

FIGS. 1A-1C illustrate examples of optical modules 100 (identified individually as optical modules 100a-100c) and components thereof according to the present disclosure. Each of the optical modules 100a-100c can include one or more of any of the components or features, in whole or in part, of any of the features described herein with respect to each other. An optical module as described herein can include or form part of an optical transmitter, an optical receiver, or both an optical transmitter and receiver. The optical module 100 includes a substrate 102 having opposing first and second sides (e.g., top and bottom sides). As described above, the substrate 102 can be an organic buildup substrate. The optical module 100 includes an interposer 104 having opposing first and second sides disposed over or above the substrate 102. The interposer 104 can be formed out of glass or other suitable material(s) with a relatively high-index of refraction. The interposer 104 can include a plurality of lenses 106 (identified individually as lenses 106a-106d) integrated on or otherwise formed on the first side of the interposer 104. For example, the lenses 106 may be fabricated via spin coating a polymer or other film on the interposer 104. While illustrated as protruding out in a convex manner, in other implementations, the lenses 106 can be recessed within the interposer 104.

The optical module 100 includes a plurality of top-emitting vertical-cavity surface-emitting lasers (e.g., VCSELs 108) flip-chipped to the second side of the interposer 104. As illustrated, the top-emitting VCSELs 108 are disposed between the substrate 102 and the interposer 104 and are configured to emit optical signals having different respective channels or wavelengths (e.g., λ₁, λ₂, λ₃, λ₄). The optical signals are configured to be combined and transmitted over a single optical fiber 110 (e.g., via a multiplexer 112), as described in more detail below. While illustrated as having four top-emitting VCSELs 108 (identified individually as VCSELs 108a, 108b, 108c, and 108d), the optical module 100 can include more than four top-emitting VCSELs (e.g., eight, sixteen, thirty-two, sixty-four) and emit additional wavelengths to be combined respectively (e.g., to increase overall bandwidth accordingly).

The optical modules described herein (e.g., optical modules 100a-100c and 200a-200c) can be optical transmitters, receivers, or transceivers. For example, the optical modules can include a plurality of top-emitting VCSELs, top-entry photodetectors, or both. With the use of top-emitting VCSELs or top-entry photodetectors rather than bottom-emitting VCSELs or substrate-entry photodetectors and the electrical and optical input/output (IO) configurations described herein, the optical modules can support wavelengths in both the one micron range (e.g., 980 nm to 1100 nm) for coarse wavelength division multiplexing (CWDM) as well as in the 850 nm range (e.g., 840 to 940 nm) for short wavelength division multiplexing (SWDM). Further, as top-emitting VCSELs or top-entry photodetectors are provided with the optical modules described herein, the top-emitting VCSELs or top-entry photodetectors can be fabricated with either transparent or non-transparent support substrate layers.

Further, as described above, the top-emitting VCSELs can be replaced or substituted with top-entry photodetectors configured to receive optical signals from the optical fiber and convert the optical signals to electrical signals for further processing. In the interest of clarity and to avoid unnecessarily obscuring the description, many of the various examples described herein refer to optical modules with top-emitting VCSELs. However, any of the example optical modules described herein can include top-entry photodetectors in addition to the top-emitting VCSELs (e.g., to form optical transceivers with transmitter and receivers) or in place of the top-emitting VCSELs.

The optical module 100 includes a plurality of electrical conductors 114 (e.g., identified individually as electrical conductors 114a-114d). Each of the electrical conductors 114 forms a respective electrical path between electrical contacts 116 (e.g., identified individually as electrical contacts 116a-116d) of respective top-emitting VCSELs 108 and the substrate 102. The electrical contacts 116 of each top-emitting VCSEL 108 include a pair of contacts (e.g., an anode contact and a cathode contact) disposed on a top side of the top-emitting VCSEL such that respective electrical paths extend or are routed from the top side of the top-emitting VCSEL 108 downward to the substrate 102. As described herein, the top side of the top-emitting VCSEL 108 refers to any VCSEL layers above a VCSEL support substrate of the top-emitting VCSEL 108. Typically, top-emitting VCSELs include one or more active layers sandwiched between upper and lower mirror layers built or otherwise formed on the support substrate. Therefore, by being disposed on the top side of the top-emitting VCSEL, the electrical contacts 116 are disposed above or over the support substrate.

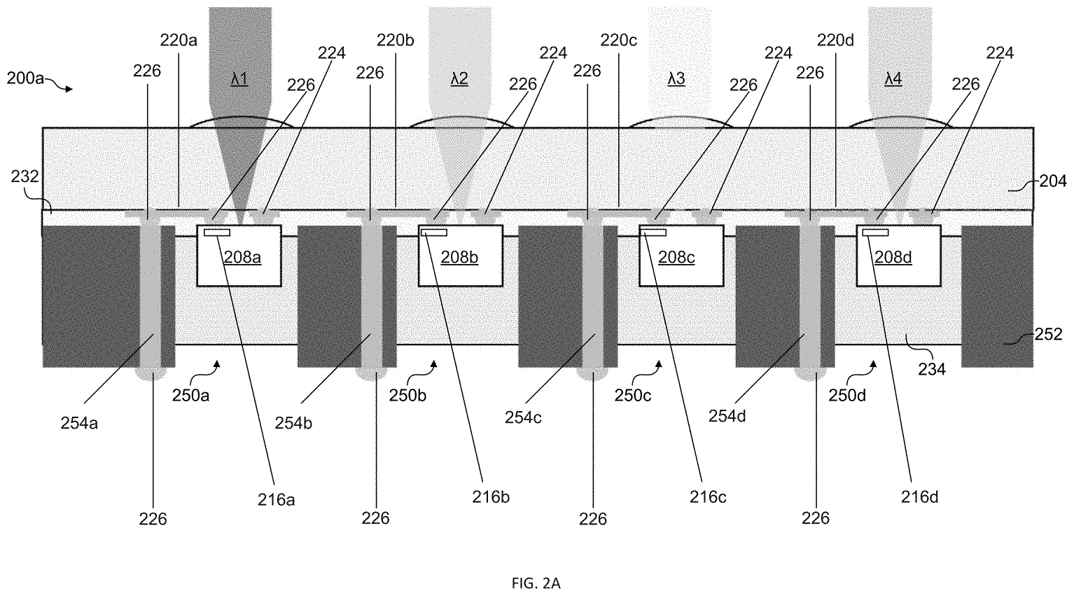

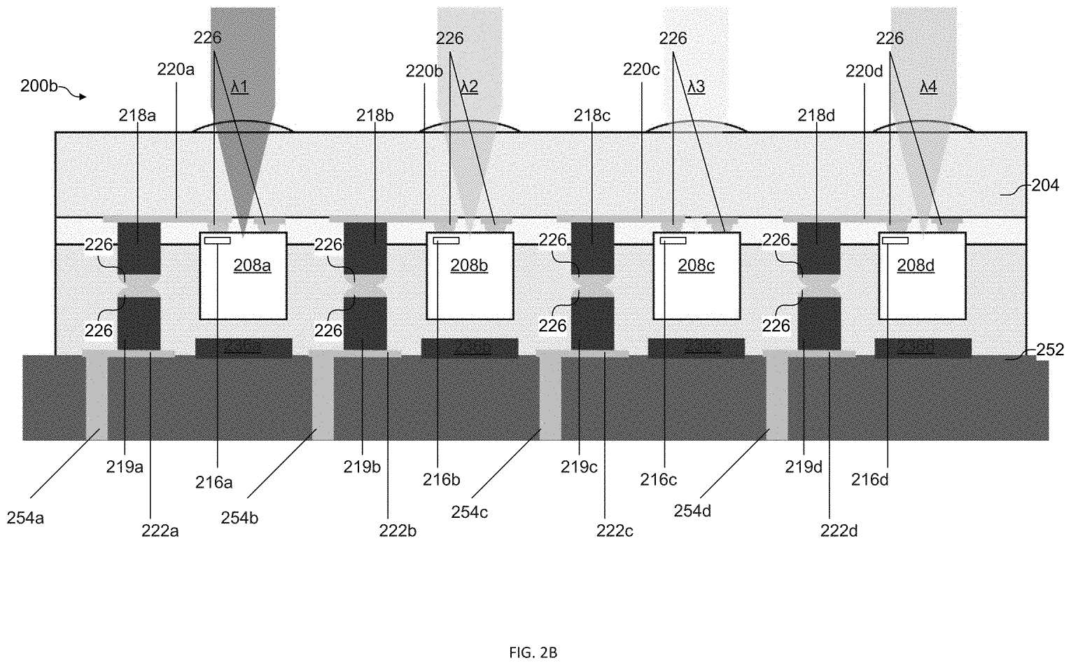

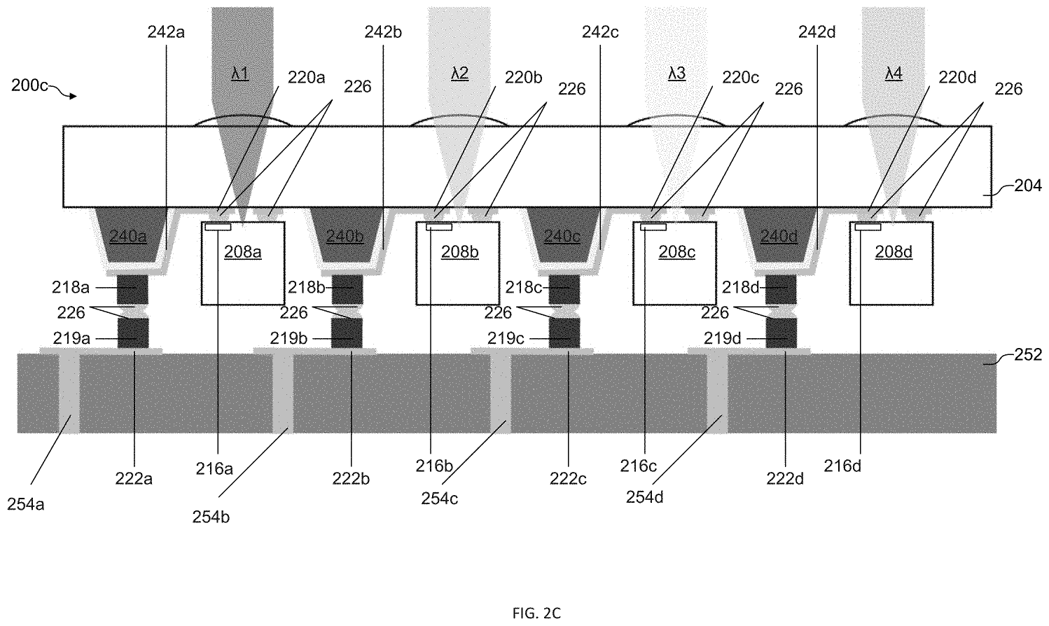

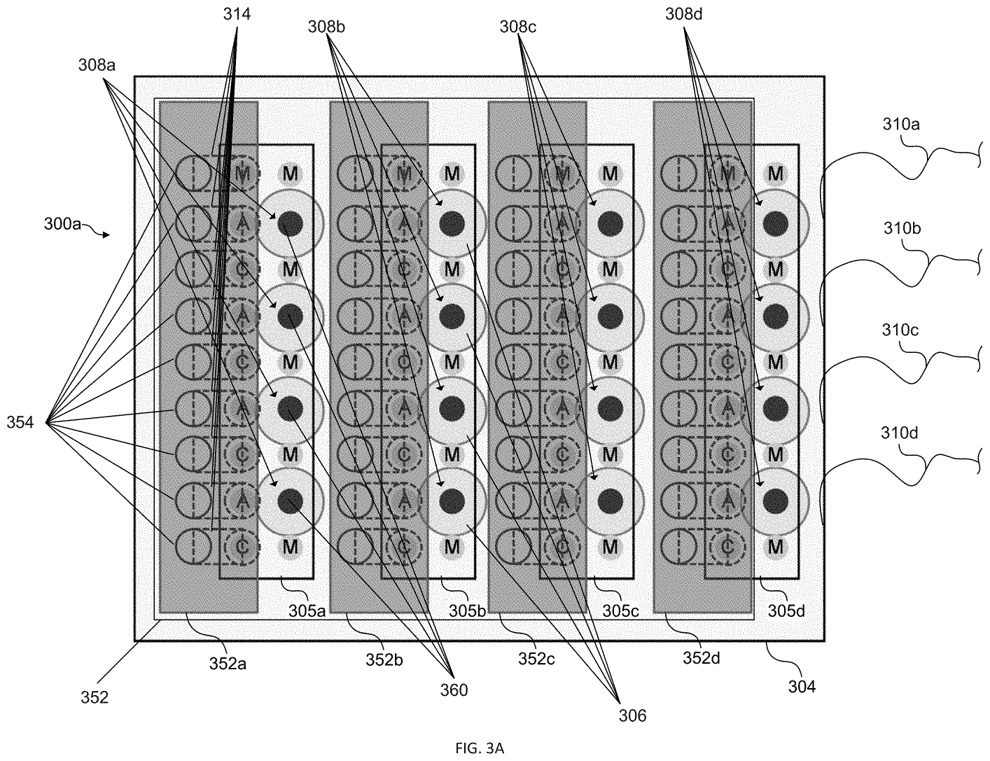

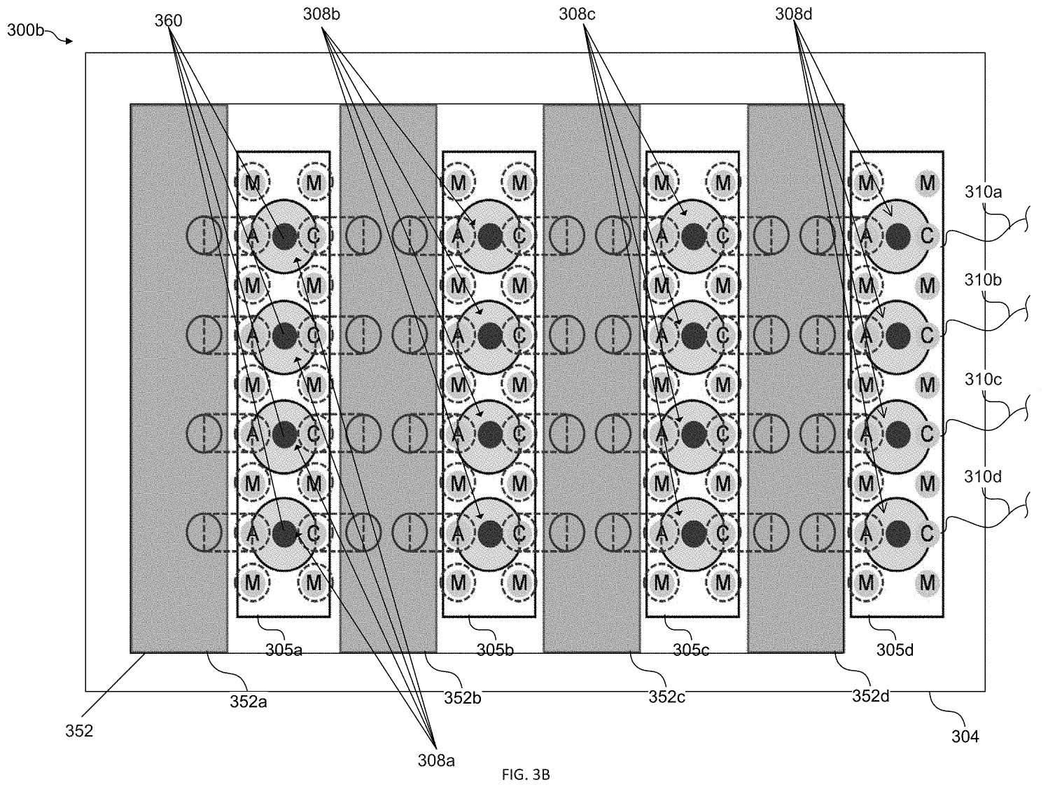

As illustrated, only one of the pair of electrical contacts 116 (e.g., the cathode or anode contact) of each top-emitting VCSEL is shown or visible. In some examples and die layouts, the other non-visible electrical contact 116 of the pair of contacts in the section views herein (FIGS. 1A-2C) is disposed behind or in the same row or column as the visible electrical contact on a same lateral side of a mesa of the top-emitting VCSEL 108 (see FIG. 3A). In other examples or die layouts, the pair of electrical contacts 116 are disposed on opposite lateral sides of the top-emitting VCSEL 108 or mesa (see FIG. 3B).

With reference to FIG. 1A, in some examples, each of the electrical conductors 114 of optical module 100a can include electrically conductive metal pillars 118 (identified individually as metal pillars 118a-118d) such as solid metal pillars or metal lined pillars. The metal pillars 118 can be copper pillars or constructed out of other suitable metal material. The metal pillars 118 extend between and electrically couple respective first pads 120 (identified individually as first pads 120a-120d) disposed on the second side of the interposer 104 and respective second pads 122 (identified individually as second pads 122a-122d) disposed on the first side of the substrate 102. The metal pillars 118 can be fabricated or otherwise formed on the interposer 104. The metal pillars have heights (e.g., 175 to 225 micrometers) that are greater than heights of the top-emitting VCSELs 108 (e.g., 150 to 200 micrometers) to provide sufficient clearance for the top-emitting VCSELs 108 between the interposer 104 and substrate 102.

The pads as described herein (e.g., the first and second pads 120 and 122) can be, for example, solder attachment pads. Each of the first pads 120 are electrically coupled to one of the electrical contacts 116 (e.g., one of the anode or cathode contacts) of a respective top-emitting VCSEL 108 (e.g., via corresponding or matching pads or traces of the top-emitting VCSEL 108). The electrical metal pillars 118 thus form electrical paths between the respective electrical contacts 116 on top sides of the top-emitting VCSELs 108 and the substrate 102 thereunder. As discussed above, the optical module 100 includes other electrical contacts 116 (e.g., the other of the anode or cathode contacts) of the pair of electrical contacts (not shown in FIG. 1A-1C or 2A-2C). These electrical contacts 116 are also electrically coupled to the substrate 102 via separate electrical conductors 114 extending between the substrate 102 and interposer 104.

The first pads 120 can be single pads (e.g., continuous pads) extending along the interposer 104 and attached to both the electrical conductors 114 and the top-emitting VCSELs 108. However, in other examples, the first pads 120 can include separate pads (e.g., two pads) configured to be coupled to the electrical conductors 114 and top-emitting VCSELS 108 respectively. The separate pads can be electrically coupled via conductive traces extending along or through the interposer 104.

The substrate 102 can also include conductive traces 128. The second pads 122 can be electrically coupled to an ASIC 130 or other suitable chip via the traces 128 (identified individually as traces 128a-128d) such that the ASIC 130 or other suitable chip can send electrical signals to respective top-emitting VCSELs 108 via the electrical paths between the substrate 102 and interposer 104 formed by the electrical conductors 114, pads (e.g., first and second pads 120 and 122, traces, and contacts 116. When the optical module 100 includes top-entry photodetectors, electrical signals converted from optical signals by the top-entry photodetectors can be sent to the ASIC 130 or other suitable chip via the electrical paths between the substrate 102 and interposer 104 for further processing.

As illustrated, the top-emitting VCSELs 108 (or top-entry photodetectors) can be mechanically coupled to respective first pads 120 via soldering (e.g., solder bumps 126 and corresponding solder reflow techniques). The optical module 100 can also include additional pads 124 (identified individually as pads 124a-124d) mechanically coupled to the respective top-emitting VCSELs 108 via soldering. Further, the metal pillars 118 can be mechanically coupled to respective second pads 120 via soldering as well. During a solder reflow process, the top-emitting VCSELs can be passively aligned with the respective lenses 106 (e.g., due to precise arrangement or position of the pads 120 and 124 on the interposer 104).

In some examples, an optical underfill layer 132 can be provided on the second side of the interposer 104 to reduce or prevent optical reflections. The optical underfill layer 132 is optically transparent and has an index of refraction matching or substantially matching that of the interposer 104. In some examples, the optical module 100 can include a thermally conductive underfill layer 134 under the optical underfill layer 132 to improve heat flow from the top-emitting VCSELs 108 to the substrate 102. Further, the first side of the substrate 102 can include heat spreaders 136 (identified individually as heat sinks 136a-136d) or heat sinks for distributing the heat from respective VCSELs 108.

As discussed above, the optical module 100 can include the multiplexer 112 and the optical fiber 110 or other suitable waveguide. Optical signals of varying wavelengths emitted by the top-emitting VCSELs 108 can be collimated by the respective lenses 106 and multiplexed or otherwise combined by the multiplexer 112 (e.g., a zig-zag multiplexer with a plurality of filters and reflectors). The combined optical signals can then be transmitted by the optical fiber 110 to, for example, another optical module, chip, or device. The optical module 100 can include an optical connector assembly (e.g., ferrule and socket) to couple the optical fiber 110 and multiplexer 112 to the interposer 104 or substrate 102. When the optical module 100 includes top-entry photodetectors, the multiplexer 112 can demultiplex optical signals transmitted to the optical module 100 via the optical fiber 110 to be received by the top-entry photodetectors.

With reference to FIG. 1B, in some examples, the optical module 100b includes a plurality of standoffs 140 (identified individually as standoffs 140a-140d) or posts disposed on the second side of the interposer 104. The standoffs 140 can be, for example, silicon (Si) standoffs bonded to or otherwise fabricated on the second side of the interposer 104. The standoffs 140 have heights (e.g., 175 to 400 micrometers) that are greater than heights of the top-emitting VCSELs 108 (e.g., 150 to 200 micrometers) to provide sufficient clearance for the top-emitting VCSELs 108 between the interposer 104 and substrate 102. The standoffs 140 extend between the interposer 104 and the substrate 102. While illustrated as having angled or slanted sidewalls, in other examples, the standoffs 140 can have vertical or substantially vertical sidewalls.

Each of the electrical conductors 114 includes conductive traces 142 (identified individually as conductive traces 142a-142d) extending along and supported by a respective standoff 140. The conductive traces 142 extend between and electrically couple respective first pads 120 (identified individually as first pads 120a-120d) disposed on the second side of the interposer 104 and respective second pads 122 (identified individually as second pads 122a-122d) disposed on the first side of the substrate 102. As described above, the first pads 120 are electrically coupled to one of respective electrical contacts 116 of the top-emitting VCSELs 108. The conductive traces 142 thus form electrical paths between the respective electrical contacts 116 on top sides of the top-emitting VCSELs 108 and the substrate 102 thereunder.

With reference to FIG. 1C, in some examples, the optical module 100c includes both the plurality of standoffs 140 disposed on the second side of the interposer 104 extending toward the substrate 102 and the metal pillars 118 as described above with respect to FIGS. 1A-1B. Each of the metal pillars 118 extends from a respective standoff 140 downward to the substrate 102. A combined height of the metal pillars 118 and standoffs 140 from which the metal pillars 118 extend is greater than a height of the top-emitting VCSELs 108 to provide sufficient clearance for the top-emitting VCSELs 108 between the interposer 104 and substrate 102. The metal pillars 118 can be shorter in height (e.g., 50 to 100 micrometers) relative to those illustrated in FIG. 1A as the standoffs 140 provide additional clearance height. In some examples, shorter metal pillars 118 may be easier to fabricate.

Each of the electrical conductors 114 includes a first portion (e.g., conductive traces 142) extending along respective standoffs 140 and a second portion (e.g., the metal pillars 118) electrically coupled to the first portion and extending from the respective standoff 140 to the substrate 102. The conductive traces 142 electrically couple respective first pads 120 to respective metal pillars 118. The conductive traces 142 extend along the respective standoff 140 to an opposing edge or side (e.g., under or rear side) of the standoff 140 opposite the second side bonded to the interposer 104 such that a portion of the conductive traces 142 is disposed between the opposing edge or side of the standoff 140 and the metal pillar 118. The metal pillar 118 electrically couples the respective conductive traces 142 to the respective second pads 122 (not illustrated in FIG. 1C) disposed on the first side of the substrate 102 (e.g., via solder bump 126 attachment). Thus, each of the electrical conductors 114 (e.g., the electrically coupled combination of conductive traces 142 and metal pillars 118) forms a respective electrical path between one of a respective electrical contact 116 on the top side of the top-emitting VCSELs 108 and the substrate 102 thereunder.

In some examples, each of the electrical conductors 114 includes a nanowire or nanotube. The nanowires extend between and electrically couple the respective first pads 120 disposed on the second side of the interposer 104 and the respective second pads 122 disposed on the first side of the substrate 102. Each of the first pads 120 are electrically coupled to one of the electrical contacts 116 of a respective top-emitting VCSEL 108. The nanowires can thus form electrical paths between the respective electrical contacts 116 on top sides of the top-emitting VCSELs 108 and the substrate 102 thereunder.

FIGS. 2A-2C illustrate examples of optical modules 200 (identified individually as optical modules 200a-200c) and components thereof according to the present disclosure. Each of the optical modules 200a-200c can include one or more of any of the components or features, in whole or in part, of any of the features described herein with respect to each other as well as optical modules 100a-100c. For example, the optical modules 200 can include a first interposer 204 similar or identical to interposer 104 described above with respect to FIGS. 1A-1C. Further, the optical modules 200 each include a second interposer 252 with opposing first and second sides disposed below the first interposer 204 (e.g., the interposer 104). The second interposer 252 can be formed from Si, glass, or another suitable material. The optical modules 200 include the second interposer 252 thereunder (e.g., in place of or instead of the substrate 102 of the optical modules 100). The second interposer 252 can be disposed over or on a substrate (not illustrated in FIGS. 2A-2C) such as the substrate 102 described above with respect to FIGS. 1A-1C. In other examples, the second interposer 252 can be disposed directly over or on an integrated circuit, chip, die, or printed circuit board.

With reference to FIG. 2A, in some examples, the second interposer 252 of optical module 200a includes a plurality of trenches or cavities 250 (identified individually as cavities 250a-250d). The cavities 250 can be through holes in some examples. In other examples, the cavities 250 can be blind holes. Top-emitting VCSELs 208 are each disposed in a respective cavity 250. The electrical conductors of the optical module 200a can include vias 254 (identified individually as vias 254a-254d), for example, through substrate vias (TSVs). The second interposer 252 can have a thickness or height of up to 400 micrometers. In some examples, the second interposer 252 can have a thickness or height of 200 micrometers. In other examples, the second interposer 252 can have a thickness or height from 250 to 300 micrometers.

The vias 254 extend through the second interposer 252 to electrically couple respective first pads 220 (identified individually as first pads 220a-220d). The first pads 220 can be solder attachment pads disposed on the second side of the first interposer 204 to the second side of the second interposer 252. Opposing ends of the vias 254 can include solder bumps 226 to couple with the first pads 220 and a substrate (e.g., the substrate 102, integrated circuit (e.g., ASIC), chip, die, or printed circuit board), respectively, under the second interposer 252.

As described above with respect to the optical module 100, each of the first pads 220 are electrically coupled to one of a pair of the electrical contacts 216 on a top side of a respective top-emitting VCSEL 208. The vias 254 thus form electrical paths between or from the respective electrical contacts 216 on top sides of the top-emitting VCSELs 208 through the second interposer 252 to the substrate (e.g., the substrate 102, integrated circuit (e.g., ASIC), chip, die, or printed circuit board) thereunder. Additionally, as described above with respect to the optical module 100, the first pads 220 can be single pads extending along the interposer 204 and attached to both the electrical vias 254 and the top-emitting VCSELs 208. However, in other examples, the first pads 220 can include separate pads configured to be coupled to the vias 254 and top-emitting VCSELS 208 respectively. The separate pads can be electrically coupled via conductive traces extending along or through the interposer 204.

The optical modules 200 can include other features as described above with respect to the optical modules 100 as described herein. For example, the optical modules 200 can also include additional pads 224 mechanically coupled to the top-emitting VCSELs 208 via soldering (e.g., solder bumps 226 and corresponding solder reflow techniques). Additionally, the optical modules 200 can include an optical underfill layer 232 that is optically transparent and has an index of refraction matching or substantially matching that of the first interposer 204 or a thermally conductive underfill layer 234 under the optical underfill layer 232. The optical modules 200 can also include one or more heat spreaders 236a-236d. Further, the optical modules 200 can also include a multiplexer/demultiplexer to multiplex or demultiplex optical signals, an optical fiber or other suitable waveguide to transmit or receive the optical signals, as well as lenses 206 for collimating or focusing the optical signals.

With reference to FIG. 2B, in some examples, the optical module 200b includes the second interposer 252 as described above with respect to optical module 200a and FIG. 2A. The optical module 200b further includes a plurality of first metal pillars 218 (identified individually as first metal pillars 218a-218d) and a plurality of second metal pillars 219 (identified individually as second metal pillars 219a-219d). The first and second metal pillars 218 and 219 can be configured identically or similarly as metal pillar 118 of optical modules 100. For example, the first metal pillars 218 are fabricated on or otherwise formed on the second side of the first interposer 204. Each of the first metal pillars 218 extends downward (e.g., towards the second interposer 252 under the first interposer 204) from respective first pads 220 disposed on the second side of the first interposer 204 between the first metal pillars 218 and the first interposer 204.

The second metal pillars 219 are fabricated on or otherwise formed on the first side of the second interposer 252. Each of the second metal pillars 219 extends upward (e.g., towards the first interposer 204 above the second interposer 252) from respective second pads 222 (identified individually as second pads 222a-222d) disposed on the first side of the second interposer 252 between the second metal pillars 219 and the second interposer 252. The first and second metal pillars 218 and 219 are in “face-to-face” contact with each other. That is opposing ends of the first and second metal pillars 218 and 219 opposite of the respective interposers they are fabricated on are coupled together. Respective first and second metal pillars 218 and 219 are coupled together (e.g., via respective solder bumps 226) such that they are in vertical or substantial vertical alignment with each other. Having two or more metal pillars (e.g., pillars 218 and 219) extending from respective interposers and coupled together allows the metal pillars to be shorter in height (e.g., 80 to 115 micrometers) relative to a single metal pillar (e.g., 175 to 225 micrometers) to provide sufficient clearance between the first and second interposers 204 and 254 for the respective top-emitting VCSELs 208. Metal pillars shorter in height may be easier to fabricate.

As described above with respect to optical module 200a, the interposer 252 includes vias 254 extending through the second interposer 252. The vias 254 can extend from the respective second pads 222 disposed on the first side of the second interposer 252 to the second side of the second interposer 252. While not illustrated in FIG. 2B, the ends of the vias 254 at the second side of the second interposer 252 can include respective solder bumps 226 to couple to a substrate (e.g., the substrate 102, integrated circuit (e.g., ASIC), chip, die, or printed circuit board), respectively, under the second interposer 252. Further, as described above with respect to the first pads 120 of optical modules 100, the first and second pads 220 and 222 of optical modules 200 can be single pads or separate pads coupled together via electrically conductive traces.

Each of the first pads 220 are electrically coupled to one of the pair of electrical contacts 216 on a top side of respective top-emitting VCSELs 208. The electrical conductors of the optical module 200b including the electrically coupled first and second metal pillars 218 and 219 and the vias 254 form electrical paths between or from the respective electrical contacts 216 on top sides of the top-emitting VCSELs 208 through the second interposer 252 to the substrate (e.g., the substrate 102, integrated circuit (e.g., ASIC), chip, die, or printed circuit board) thereunder.

With reference to FIG. 2C, in some examples, the optical module 200c includes the second interposer 252 as described above with respect to optical modules 200a and 200b as well as the plurality of first metal pillars 218 and second metal pillars 219. The optical module 200c further includes a plurality of standoffs 240 (identified individually as standoffs 240a-240d) disposed on the second side of the first interposer 204 extending downward toward the second interposer 252. The standoffs 240 can be configured identically or similarly as standoffs 140 described above bonded to or otherwise formed on the second side of the first interposer 204.

As illustrated, the first pillars 218 are fabricated on or otherwise formed an under or rear side of respective standoffs 240. Each of the first metal pillars 218 extends downward (e.g., towards the second interposer 252 under the first interposer 204). The second metal pillars 219 are fabricated on or otherwise formed on the first side of the second interposer 252. Each of the second metal pillars 219 extends upward (e.g., towards the first interposer 204 above the second interposer 252) such that first and second metal pillars 218 and 219 are in “face-to-face” contact with each other.

Respective first and second metal pillars 218 and 219 can be coupled together (e.g., via respective solder bumps 226) such that they are in vertical or substantial vertical alignment with each other as described above with respect to the metal pillars of optical module 200b. By including standoffs 240, the heights of the first and second metal pillars 218 and 219 can be further reduced or decreased relative to single metal pillars as well as the metal pillars of optical module 200b as the standoffs 240 provide additional clearance height between the interposers 204 and 252. For example, with standoffs 240 having heights of 125 micrometers, the metal pillars 218 and 219 can have heights of 25 micrometers each such that sufficient clearance is provided for top-emitting VCSELs of 150 micrometers in height to be disposed between the interposers 204 and 252.

Each of the electrical conductors of the optical module 200c includes conductive traces 242 (identified individually as conductive traces 242a-242d). The conductive traces 242 can be configured identically or similarly as conductive traces 142 described above with respect to optical modules 100b and 100c. For example, the conductive traces 242 extend from the first pads 220 disposed on the second side of the first interposer 204 and along respective standoffs 240. The conductive traces 242 electrically couple respective first pads 220 to respective metal pillars 218 extending from the standoffs 240. The conductive traces 242 extend along the respective standoffs 240 to an opposing edge or side (e.g., under or rear side) of the standoff 240 opposite the second side bonded to the interposer 240 such that a portion of the conductive traces 242 is disposed between the opposing edge or side of the standoff 240 and the metal pillar 218.

The metal pillars 218 and 219 electrically couple the respective conductive traces 242 to the respective second pads 222 disposed on the first side of the second interposer 252. Each of the first pads 220 are electrically coupled to one of the pair of electrical contacts 216 on a top side of respective top-emitting VCSELs 208. The second interposer 252 can include vias 254 as described herein. Thus, the electrical conductors of the optical module 200c including the electrically coupled first and second metal pillars 218 and 219, conductive traces 242, and the vias 254 form electrical paths between or from the respective electrical contacts 216 on top sides of the top-emitting VCSELs 208, along the respective standoffs 240, through the second interposer 252, and to a substrate (e.g., the substrate 102, integrated circuit (e.g., ASIC), chip, die, or printed circuit board) thereunder.

Referring to FIGS. 3A-3B, top section views of example die or package layouts of arrays of the optical modules as described herein (e.g., optical modules 100a-100c and 200a-200c) are illustrated. As described above, top-emitting VCSELs 308 can be replaced with top-entry photodetectors. The die layouts 300a and 300b can include sixteen top-emitting VCSELs 308 (e.g., in a 4×4 arrangement or layout) such that optical signals from each set or group of four top-emitting VCSELs 308 (identified individually as VCSELs 308a-308d) with different wavelengths (e.g., λ₁, λ₂, λ₃, λ₄) are configured to be multiplexed or otherwise combined to be transmitted over a respective optical fiber 310 (identified individually as optical fibers 310a-310d). In other examples, the die layouts 300a and 300b can include more or less than sixteen top-emitting VCSELs 308. Each top-emitting VCSEL 308 includes an active mesa 360 and light emitted from the top-emitting VCSELs 308 can be collimated by a lens 306 to be multiplexed as described above.

Each top-emitting VCSEL 308 is flip-chipped or otherwise coupled to a first interposer or substrate 304 (e.g., interposer 204 or substrate 104 as described herein) via mechanical attachments M (e.g., pads 124 or 224 and corresponding solder bumps). As described above, different channels or wavelengths (e.g., λ₁, λ₂, λ₃, λ₄) of each set or group of top-emitting VCSELs 308 can be combined and transmitted over a respective optical fiber 310. The VCSELs 308 configured to emit the same wavelength can be coupled to or otherwise formed on the same chip or VCSEL support substrate 305 (identified as VCSEL support substrates 305a-305d) and then flip-chipped to the first interposer or substrate 304. For example, the VCSELs 308a configured to emit wavelength λ₁ can be formed on the same VCSEL support substrate 305a, the VCSELs 308b configured to emit wavelength λ₂ can be formed on the same VCSEL support substrate 305b, the VCSELs 308c configured to emit wavelength λ₃ can formed on the same VCSEL support substrate 305c, and the VCSELs 308d configured to emit wavelength λ₄ can be formed on the same VCSEL support substrate 305d.

Each top-emitting VCSEL 308 includes a pair of electrical contacts (e.g., identified as anode contact A and cathode contact C). The electrical contacts can be electrically coupled to a second interposer or substrate 352 (e.g., interposer 252 or substrate 102 as described herein) under the first interposer or substrate 304 via electrical conductors 314. As described above with respect to the second interposer or substrate 252, the second interposer or substrate 352 can include a plurality of cavities or trenches spacing apart or between portions or sections of the second interposer or substrate 352 (identified individually as second interposer or substrate sections 352a-352d). With reference to FIG. 3A, in some examples, the pairs of electrical contacts of the VCSELs 308 can be disposed or positioned on a same lateral side of respective active mesas 360 of the VCSELs 308. With reference to FIG. 3B, in other examples, the pairs of electrical contacts of the VCSELs 308 can be disposed or positioned on opposing lateral sides of the respective active mesas 360 of the VCSELs 308.

The electrical conductors 314 can be configured according to any of the electrical conductors described herein with respect to optical modules 100a-100c and 200a-200c. For example, as illustrated in FIGS. 3A-3B, the electrical conductors 314 can include vias 354 extending through the second interposer or substrate 352 to form electrical paths between the electrical contacts on a top-side of each top-emitting VCSEL 308 and the second side (e.g., under or rear side) of the second interposer or substrate 352 thereunder. As described above, the electrical paths can include corresponding pads and traces between the electrical contacts and vias. Further in some examples, the electrical conductors 314 can electrically couple the electrical contacts to a substrate (e.g., the substrate 102, integrated circuit (e.g., ASIC), chip, die, or printed circuit board) under the second interposer or substrate 352.

In the foregoing description, numerous details are set forth to provide an understanding of the subject disclosed herein. However, implementations may be practiced without some or all of these details. Other implementations may include additions, modifications, or variations from the details discussed above. It is intended that the appended claims cover such modifications and variations. The specification and drawings are, accordingly, to be regarded as illustrative rather than restrictive. Additionally, in the interest of clarity and to avoid unnecessarily obscuring the description, other details describing well-known structures and systems often associated with optical modules (e.g., VCSEL contact pads, traces between pads, driver circuitry), have not been set forth herein in the description of the various examples of the present disclosure.

It will be recognized that the terms “comprising,” “including,” and “having,” as used herein, are specifically intended to be read as open-ended terms of art. The term “or,” in reference to a list of two or more items, covers all of the following interpretations of the word: any of the items in the list, all of the items in the list, and any combination of the items in the list. As used herein, the terms “connected,” “coupled,” or any variant thereof means any connection or coupling, either direct or indirect (e.g., having additional intervening components or elements), between two or more elements, nodes, or components; the coupling or connection between the elements can be physical, mechanical, logical, optical, electrical, or a combination thereof.

In the Figures, identical reference numbers identify identical, or at least generally similar, elements. To facilitate the discussion of any particular element, the most significant digit or digits of any reference number refers to the Figure in which that element is first introduced. For example, element 110 is first introduced and discussed with reference to FIG. 1.

The status of the claims:

1. An optical module comprising:
a substrate having opposing first and second sides;
a first interposer having opposing first and second sides;
a plurality of top-emitting vertical-cavity surface-emitting lasers (VCSELs) flip-chipped to the second side of the first interposer, the top-emitting VCSELs disposed between the substrate and the first interposer and configured to emit optical signals having different wavelengths, the optical signals configured to be combined and transmitted over a single optical fiber; and
a plurality of electrical conductors forming electrical paths between electrical contacts of the top-emitting VCSELs and the substrate.

2. The optical module of claim 1, wherein the electrical contacts of each top-emitting VCSEL include an anode contact and a cathode contact disposed on a top side of the top-emitting VCSEL such that respective electrical paths extend from the substrate to the top-side of the top-emitting VCSEL.

3. The optical module of claim 1, wherein each of the electrical conductors comprises a metal pillar extending between and electrically coupling a respective first pad disposed on the second side of the first interposer and a respective second pad disposed on the first side of the substrate, each of the first pads electrically coupled to one of the electrical contacts of a respective top-emitting VCSEL.

4. The optical module of claim 1, further comprising a plurality of standoffs disposed on the second side of the first interposer extending between the first interposer and the substrate and wherein each of the electrical conductors extends along a respective standoff to form a respective electrical path between a respective electrical contact and the substrate.

5. The optical module of claim 1, further comprising a plurality of standoffs disposed on the second side of the first interposer extending toward the substrate and wherein each of the electrical conductors comprises a first portion extending along a respective standoff and a second portion, the second portion including a metal pillar electrically coupled to the first portion and extending from the respective standoff to the substrate such that each of the electrical conductors forms a respective electrical path between a respective electrical contact and the substrate.

6. The optical module of claim 1, wherein each of the electrical conductors comprises a nanowire extending between and electrically coupling a respective first pad disposed on the second side of the first interposer and a respective second pad disposed on the first side of the substrate, each of the first pads electrically coupled to one of the electrical contacts of a respective top-emitting VCSEL.

7. The optical module of claim 1, wherein the substrate is a second interposer including a plurality of cavities, wherein each of the top-emitting VCSELs are disposed in a respective cavity, and wherein each of the electrical conductors extends through the second interposer to electrically couple respective first pads disposed on the second side of the first interposer to the second side of the second interposer, each of the first pads electrically coupled to one of the electrical contacts of a respective top-emitting VCSEL.

8. The optical module of claim 1, wherein each of the cavities are blind holes formed through the second interposer.

9. The optical module of claim 1, wherein the substrate is a second interposer, each of the electrical conductors comprising:
first, second, and third portions;
wherein the first portion comprises a first metal pillar extending from a first pad disposed on the second side of the first interposer towards the second interposer;
wherein the second portion comprises a second metal pillar extending from a second pad disposed on the first side of the second interposer towards the first interposer, the first and second metal pillars electrically coupled and in substantial vertical alignment with each other;
wherein the third portion extends from the second pad through the second interposer; and
wherein each of the electrical conductors electrically couples respective first pads disposed on the second side of the first interposer to the second side of the second interposer, each of the first pads electrically coupled to one of the electrical contacts of a respective top-emitting VCSEL.

10. The optical module of claim 1, further comprising a plurality of standoffs disposed on the second side of the first interposer extending toward the substrate and wherein the substrate is a second interposer, each of the electrical conductors comprising:
first, second, third, and fourth portions;
wherein the first portion extends from a first pad disposed on the second side of the first interposer along a respective standoff;
wherein the second portion comprises a first metal pillar electrically coupled to the first portion and extending from the respective standoff towards the second interposer;
wherein the third portion comprises a second metal pillar extending from a second pad disposed on the first side of the second interposer towards the first interposer, the first and second metal pillars electrically coupled and in substantial vertical alignment with each other;
wherein the fourth portion extends from the second pad through the second interposer; and
wherein each of the electrical conductors electrically couples respective first pads to the second side of the second interposer, each of the first pads electrically coupled to one of the electrical contacts of a respective top-emitting VCSEL.

11. An optical module comprising:
a substrate having opposing first and second sides;
a first interposer having opposing first and second sides;
a plurality of top-entry photodetectors flip-chipped to the second side of the first interposer, the top-entry photodetectors disposed between the substrate and the first interposer and configured to receive optical signals having different wavelengths, the optical signals configured to be separated by a demultiplexer prior to being received by respective photodetectors; and
a plurality of electrical conductors forming electrical paths between electrical contacts of the top-entry photodetectors and the substrate.

12. The optical module of claim 11, wherein the electrical contacts of each top-entry photodetector include an anode contact and a cathode contact disposed on a top side of the top-entry photodetector such that respective electrical paths extend from the substrate to the top-side of the top-entry photodetector.

13. The optical module of claim 11, wherein each of the electrical conductors comprises a metal pillar extending between and electrically coupling a respective first pad disposed on the second side of the first interposer and a respective second pad disposed on the first side of the substrate, each of the first pads electrically coupled to one of the electrical contacts of a respective top-entry photodetector.

14. The optical module of claim 11, further comprising a plurality of standoffs disposed on the second side of the first interposer extending between the first interposer and the substrate and wherein each of the electrical conductors extends along a respective standoff to form a respective electrical path between a respective electrical contact and the substrate.

15. The optical module of claim 11, further comprising a plurality of standoffs disposed on the second side of the first interposer extending toward the substrate and wherein each of the electrical conductors comprises a first portion extending along a respective standoff and a second portion, the second portion including a metal pillar electrically coupled to the first portion and extending from the respective standoff to the substrate such that each of the electrical conductors forms a respective electrical path between a respective electrical contact and the substrate.

16. The optical module of claim 11, wherein each of the electrical conductors comprises a nanowire extending between and electrically coupling a respective first pad disposed on the second side of the first interposer and a respective second pad disposed on the first side of the substrate, each of the first pads electrically coupled to one of the electrical contacts of a respective top-entry photodetector.

17. The optical module of claim 11, wherein the substrate is a second interposer including a plurality of cavities, wherein each of the top-entry photodetectors are disposed in a respective cavity, and wherein each of the electrical conductors extends through the second interposer to electrically couple respective first pads disposed on the second side of the first interposer to the second side of the second interposer, each of the first pads electrically coupled to one of the electrical contacts of a respective top-entry photodetector.

18. The optical module of claim 11, wherein each of the cavities are blind holes formed through the second interposer.

19. The optical module of claim 11, wherein the substrate is a second interposer, each of the electrical conductors comprising:
first, second, and third portions;
wherein the first portion comprises a first metal pillar extending from a first pad disposed on the second side of the first interposer towards the second interposer;
wherein the second portion comprises a second metal pillar extending from a second pad disposed on the first side of the second interposer towards the first interposer, the first and second metal pillars electrically coupled and in substantial vertical alignment with each other;
wherein the third portion extends from the second pad through the second interposer; and
wherein each of the electrical conductors electrically couples respective first pads disposed on the second side of the first interposer to the second side of the second interposer, each of the first pads electrically coupled to one of the electrical contacts of a respective top-entry photodetector.

20. The optical module of claim 11, further comprising a plurality of standoffs disposed on the second side of the first interposer extending toward the substrate and wherein the substrate is a second interposer, each of the electrical conductors comprising:
first, second, third, and fourth portions;
wherein the first portion extends from a first pad disposed on the second side of the first interposer along a respective standoff;
wherein the second portion comprises a first metal pillar electrically coupled to the first portion and extending from the respective standoff towards the second interposer;
wherein the third portion comprises a second metal pillar extending from a second pad disposed on the first side of the second interposer towards the first interposer, the first and second metal pillars electrically coupled and in substantial vertical alignment with each other;
wherein the fourth portion extends from the second pad through the second interposer; and
wherein each of the electrical conductors electrically couples respective first pads to the second side of the second interposer, each of the first pads electrically coupled to one of the electrical contacts of a respective top-entry photodetector.
